(19) United States
(12) Patent Application Publication
(10) Pub. No.: US 2023/0413598 A1
(43) Pub. Date: Dec. 21, 2023

(54) LIGHT-EMITTING DEVICE AND ELECTRONIC APPARATUS INCLUDING THE SAME

(71) Applicant: Samsung Display Co., Ltd., Yongin-si (KR)

(72) Inventors: Sehun KIM, Yongin-si (KR); Changhee LEE, Yongin-si (KR); Yeo Geon Yoon, Yongin-si (KR)

(21) Appl. No.: 18/322,945

(22) Filed: May 24, 2023

(30) Foreign Application Priority Data
Jun. 16, 2022 (KR) 10-2022-0073757

(51) Int. Cl. H10K 50/828; H10K 50/15; H10K 50/17; H10K 50/16; C09K 11/06

(52) U.S. Cl. CPC H10K 50/828; H10K 50/15; H10K 50/171; H10K 50/16; C09K 11/06; H10K 2102/102

(57) ABSTRACT

A light-emitting device in which a hole injection layer is disposed between an emission layer and a second electrode, and the hole injection layer includes graphene and contacts the second electrode, and a first electrode is a cathode.

### CROSS-REFERENCE TO RELATED APPLICATION

This application claims priority under to Korean Patent Application No. 10-2022-0073757, filed on Jun. 16, 2022 in the Korean Intellectual Property Office, and all the benefits accruing therefrom under 35 U.S.C. § 119, the entire content of which is herein incorporated by reference.

### BACKGROUND

### 1. Field

One or more embodiments relate to a light-emitting device and an electronic apparatus including the same.

### 2. Description of the Related Art

Light-emitting devices are self-emissive devices that, as compared with devices of the related art, have wide viewing angles, high contrast ratios, short response times, and excellent characteristics in terms of luminance, driving voltage, and response speed.

A light-emitting device may have a structure in which a first electrode (or a second electrode) is arranged on a substrate, and a hole transport region, an emission layer, an electron transport region, and the second electrode (or the first electrode) are sequentially formed on the first electrode (or the second electrode). Holes provided from the first electrode (or the second electrode) may move toward the emission layer through the hole transport region, and electrons provided from the second electrode (or the first electrode) may move toward the emission layer through the electron transport region. Carriers, such as holes and electrons, recombine in the emission layer to produce light.

### SUMMARY

One or more embodiments include a device with improved efficiency and lifespan, as compared to devices of the related art.

Additional aspects will be set forth in part in the description which follows and, in part, will be apparent from the description, or may be learned by practice of the presented embodiments of the disclosure.

According to one or more embodiments, a light-emitting device includes

a first electrode,

a second electrode facing the first electrode, and

an interlayer between the first electrode and the second electrode and including an emission layer,

wherein the interlayer further comprises a hole injection layer that includes graphene, the hole injection layer disposed between the emission layer and the second electrode,

wherein the first electrode is a cathode.

According to one or more embodiments, an electronic apparatus includes the light-emitting device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic view of a structure of a light-emitting device according to an embodiment;

FIG. 2 is a cross-sectional view of a light-emitting apparatus according to an embodiment; and

FIG. 3 is a cross-sectional view of a light-emitting apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

The terminology used herein is for the purpose of describing particular embodiments only and is not intended to be limiting. As used herein, the singular forms (“a,” “an,” and “the” are intended to include the plural forms, including “at least one,” unless the content clearly indicates otherwise. “At least one” is not to be construed as limiting “a” or “an.” Accordingly, the expression “at least one of a, b or c” indicates only a, only b, only c, both a and b, both a and c, both b and c, all of a, b, and c, or variations thereof. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or ±5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

An electroluminescent quantum dot (EL-QD) light-emitting device refers to a light-emitting device that includes quantum dots, which are nano-sized semiconductor particles in an emission layer of the EL-QD.

An organic light-emitting device (OLED), which uses an organic luminescent material, may implement a single color such as red, green, blue, and the like according to the type of devices, but there are limitations to the quality of color and/or image, e.g., the mixing or contrasting of colors in the light emitted. However, by carefully controlling or adjusting the size of the quantum dots to provide a more natural (refined) color, that is, through emission of light with a relatively narrow luminescence waveform (peak emission) to improve upon color reproducibility, the EL-QD light-emitting device surpasses OLED in image/color quality and performance. Moreover, the light emitted from an EL-QD may exhibit luminance values that is just as good as luminance values from an OLED.

The nano-sized quantum dots emit light when electrons in an excited state relax from a conduction band to a valence band. The smaller the particle of the quantum dot, the shorter the wavelength of light is emitted, and the larger the particle of the quantum dot, the longer the wavelength of light is emitted. This is a unique electro-optical characteristic that is different from semiconductor materials of the related art, and visible light of a desired wavelength may be expressed by adjusting the size of the quantum dots, and various colors may simultaneously be implemented by using quantum dots of various sizes, e.g., particle diameters.

Quantum dots are different from phosphorescent or fluorescent emitters of the related OLED art, and thus, new methods for improving the performance of quantum dot devices are of interest and require additional development. The luminescence efficiency of an emission layer including the quantum dots is determined by quantum efficiency, charge carrier balance, out-coupling efficiency, leakage current, and the like of the quantum dots. That is, in order to improve the luminescence efficiency of the emission layer, the ability to control the movement of excitons is likely needed, e.g., the ability to form and/or confine the excitons to the emission layer. In other words, one may need to efficiently control the movement or transport of holes and electrons to the quantum dots, and thereby, reduce or minimize leakage current, or the like.

The operation of an EL-QD light-emitting device may be controlled in-part with n-type oxide thin-film transistors having high mobility characteristics, which may be applicable to a large-area display. Accordingly, development of an EL-QD light-emitting device with an inverted structure may be necessary.

To this end, injection of holes to a metal electrode (anode) likely needs to be more facile, and oxidation of the metal electrode needs to be minimized or reduced by blocking residual solvent in a functional layer formed by a solution process or preventing the diffusion of out-gassing components.

According to one or more embodiments, a light-emitting includes:

a first electrode;

a second electrode facing the first electrode; and

an interlayer located between the first electrode and the second electrode and comprising an emission layer,

wherein the interlayer further comprises a hole injection layer that includes graphene, the hole injection layer disposed between the emission layer and contacts the second electrode,

wherein the first electrode is a cathode.

For example, the hole injection layer may be in direct contact with the second electrode.

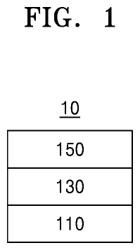

FIG. 1 is a schematic cross-sectional representation of a light-emitting device 10 according to an embodiment. The light-emitting device 10 includes a first electrode 110, an interlayer 130, and a second electrode 150. Hereinafter, the structure of the light-emitting device 10 according to an embodiment and a method of manufacturing the light-emitting device 10 will be described with reference to FIG. 1.

### First Electrode 110

In FIG. 1, a substrate (not shown) may be additionally located under the first electrode 110 or on the second electrode 150. As the substrate, a glass substrate or a plastic substrate may be used. In one or more embodiments, the substrate may be a flexible substrate, and may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be a cathode, which is an electron injection electrode, and as a material for forming the first electrode 110, a metal, an alloy, an electrically conductive compound, or any combination thereof, each having a low work function, may be used.

In an embodiment, the first electrode may include indium tin oxide (ITO), indium zinc oxide (IZO), tin oxide (SnO₂), zinc oxide (ZnO), or any combination thereof.

In one or more embodiments, the material for forming the first electrode 110 may include silver (Ag), magnesium (Mg), aluminum (AI), platinum (Pt), palladium (Pd), gold (Au), nickel (Ni), neodymium (Nd), iridium (Ir), chromium (Cr), lithium (Li), calcium (Ca), indium (In), or any combination thereof. The first electrode may have a single-layered structure consisting of a single layer or a multi-layered structure including a plurality of layers.

When the first electrode 110 is a reflective electrode, the material for forming the first electrode 110 may include ITO, IZO, SnO₂, ZnO, or any combination thereof, and at the same time, may include Ag, Mg, Al, Pt, Pd, Au, Ni, Nd, Ir, Cr, Li, Ca, In, or any combination thereof. For example, the first electrode may have a two-layered structure of Ag/ITO or a three-layered structure of ITO/Ag/ITO.

### Interlayer 130

The term “interlayer” as used herein refers to a single layer and/or all of a plurality of layers located between the first electrode and the second electrode of the light-emitting device. Thus, the “interlayer” in FIG. 1 is shown as a single layer, but may include a plurality of multiple layers.

The interlayer 130 may be located (disposed) on the first electrode 110. The interlayer 130 may include an emission layer.

The interlayer 130 may further include a hole transport region located (disposed) between the second electrode 150 and the emission layer and an electron transport region located (disposed) between the emission layer and the first electrode 110.

The interlayer 130 may further include, in addition to various organic materials, a metal-containing compound such as an organometallic compound, an inorganic material such as quantum dots, or the like, e.g., in the emission layer.

In an embodiment, the interlayer 130 may include i) two or more emitting units sequentially stacked between the first electrode 110 and the second electrode 150, and ii) a charge generation layer located (positioned) between each of the two or more emitting units. When the interlayer 130 includes emitting units and a charge generation layer as described above, the light-emitting device 10 may be a tandem light-emitting device.

### Electron Transport Region in Interlayer 130

The electron transport region may have i) a single-layered structure consisting of a single layer consisting of a single material, ii) a single-layered structure consisting of a single layer consisting of a plurality (two or more) of different materials, or iii) a multi-layered structure including a plurality of layers, each including different materials.

In an embodiment, the interlayer of the light-emitting device may further include an electron transport region located between the first electrode and the emission layer and including an electron injection layer, an electron transport layer, a hole blocking layer, or any combination thereof.

In an embodiment, the electron injection layer and the electron transport layer may be in contact with each other. For example, the electron injection layer and the electron transport layer may physically be in direct contact with each other.

In an embodiment, the electron injection layer may be in contact with the first electrode 110. For example, the electron injection layer and the first electrode 110 may physically be in direct contact with each other.

In an embodiment, the electron injection layer may be in contact with the emission layer. For example, the electron injection layer and the emission layer may physically be in direct contact with each other. In this case, the electron transport layer may not be included.

In an embodiment, the electron transport layer and the emission layer may be in contact with each other. For example, the electron transport layer and the emission layer may physically be in direct contact with each other.

According to an embodiment, the electron injection layer may include an oxide including Zn, Ti, Zr, Sn, Mg, Co, Ni, Mn, Y, Al, or any combination thereof.

For example, the electron injection layer may include a compound represented by Formula 10:

MₓO_{y} Formula 10

wherein, in Formula 10, M may include Zn, Ti, Zr, Sn, or any combination thereof, and x and y may each independently be an integer from 1 to 5.

When M is Zn, Formula 10 may be represented by Formula 20:

Zn_{1-z}M′_{z}O Formula 20

wherein, in Formula 2, M′ may be Mg, Co, Ni, Zr, Mn, Sn, Y, Al, or any combination thereof, and 0≤z<0.5.

In an embodiment, the electron transport layer may include a phosphine oxide compound.

In an embodiment, the phosphine oxide compound may include one of the compounds 101 to 109.

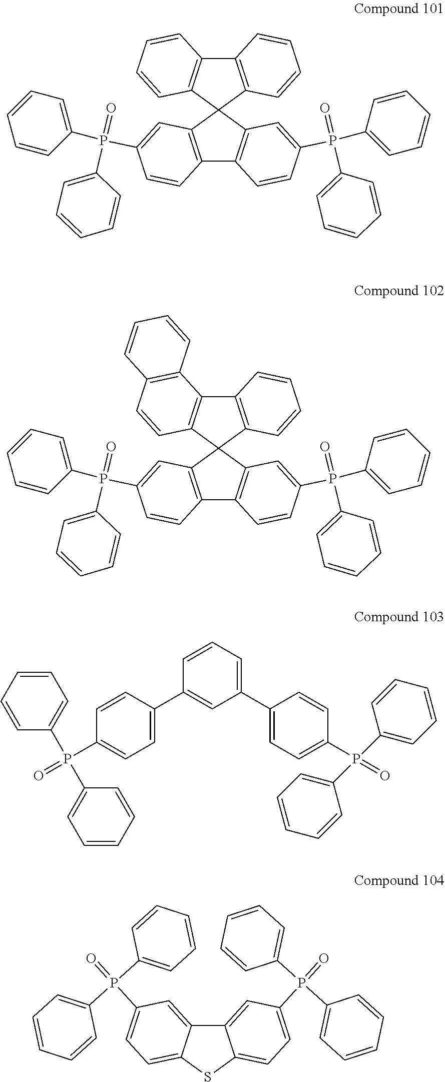 [SMILES: O=P(c1ccccc1)(c1ccccc1)c1ccc2c(c1)C1(c3ccccc3-c3ccccc31)c1cc(P(=O)(c3ccccc3)c3ccccc3)ccc1-2 ; O=P(c1ccccc1)(c1ccccc1)c1ccc2c(c1)C1(c3cc(P(=O)(c4ccccc4)c4ccccc4)ccc3-2)c2ccccc2-c2c1ccc1ccccc21 ; O=P(c1ccccc1)(c1ccccc1)c1ccc(-c2cccc(-c3ccc(P(=O)(c4ccccc4)c4ccccc4)cc3)c2)cc1 ; O=P(c1ccccc1)(c1ccccc1)c1ccc2sc3ccc(P(=O)(c4ccccc4)c4ccccc4)cc3c2c1]

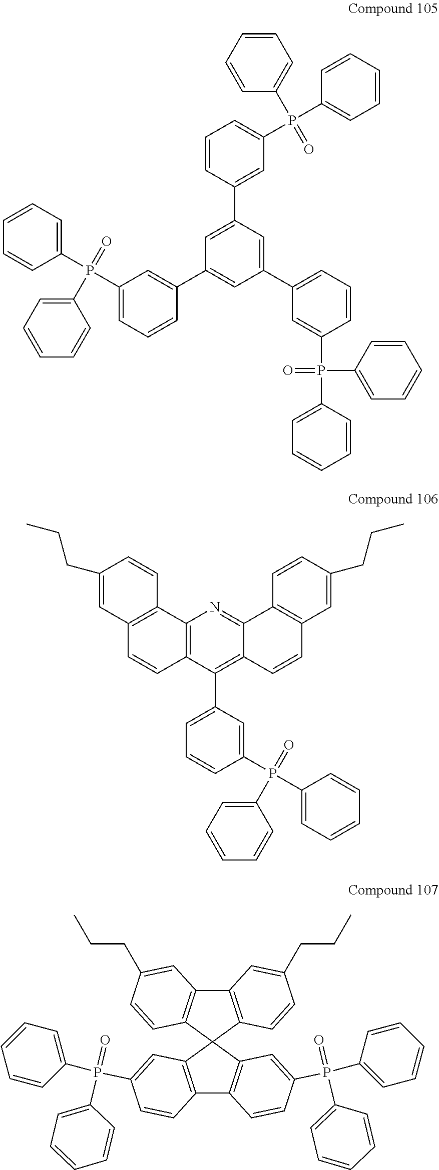 [SMILES: O=P(c1ccccc1)(c1ccccc1)c1cccc(-c2cc(-c3cccc(P(=O)(c4ccccc4)c4ccccc4)c3)cc(-c3cccc(P(=O)(c4ccccc4)c4ccccc4)c3)c2)c1 ; CCCc1ccc2c(ccc3c(-c4cccc(P(=O)(c5ccccc5)c5ccccc5)c4)c4ccc5cc(CCC)ccc5c4nc32)c1 ; CCCc1ccc2c(c1)-c1cc(CCC)ccc1C21c2cc(P(=O)(c3ccccc3)c3ccccc3)ccc2-c2ccc(P(=O)(c3ccccc3)c3ccccc3)cc21]

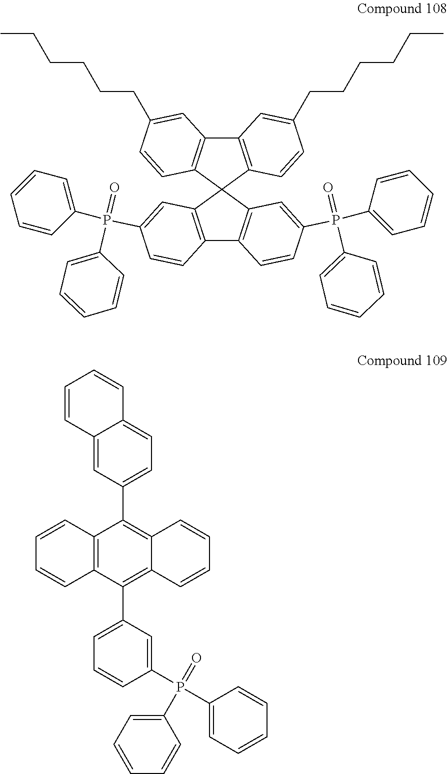 [SMILES: CCCCCCc1ccc2c(c1)-c1cc(CCCCCC)ccc1C21c2cc(P(=O)(c3ccccc3)c3ccccc3)ccc2-c2ccc(P(=O)(c3ccccc3)c3ccccc3)cc21 ; O=P(c1ccccc1)(c1ccccc1)c1cccc(-c2c3ccccc3c(-c3ccc4ccccc4c3)c3ccccc23)c1]

In an embodiment, a thickness of the electron injection layer may be in a range of about 100 angstroms (Å) to about e.g., about 3,000 Å. For example, a thickness of the electron injection layer may be in a range of about 200 Å to about 2,500 Å, or about 300 Å to about 1,800 Å.

In an embodiment, a thickness of the electron transport layer may be in a range of about 50 Å to about 600 Å, e.g., about 400 Å. For example, a thickness of the electron transport layer may be in a range of about 100 Å to about 250 Å.

When the thicknesses of the electron injection layer and the electron transport layer are within the ranges above, electron flow from the first electrode 110 to the emission layer may be efficiently controlled.

In an embodiment, the electron transport layer may further include a metal-containing material. For example, the metal-containing material may include an n-dopant. For example, the metal-containing material may include a Li complex and/or a Ca complex.

In the electron transport layer, an amount of the metal-containing material may be in a range of about 0.1 weight percent (wt %) to about 900 wt % based on 100 wt % of the phosphine oxide compound (see below).

When the amount of the metal-containing material is within the range above, the light-emitting device may exhibit excellent efficiency and lifespan.

In an embodiment, the metal-containing material may include at least one of the following compounds 201 to 209.

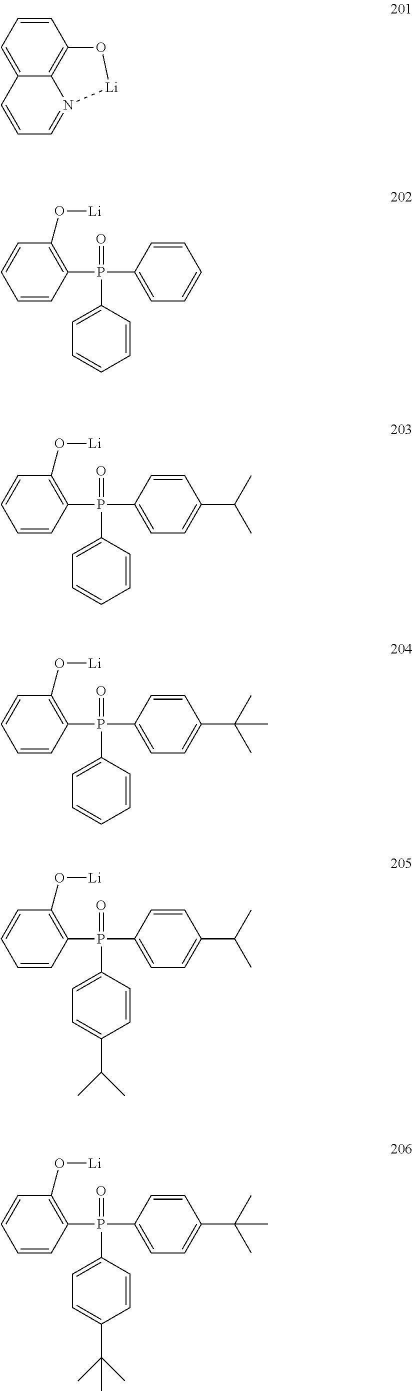

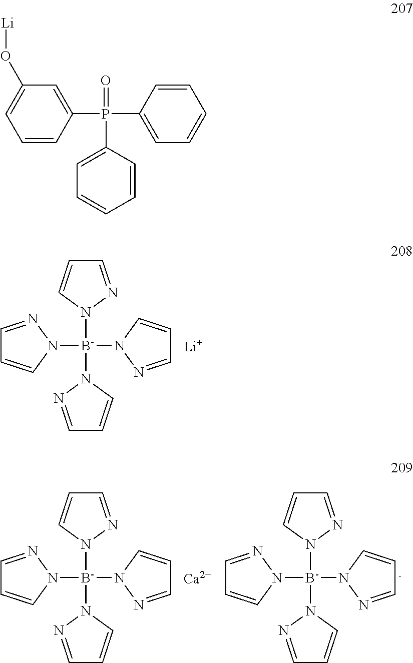

In an embodiment, the interlayer may include a layer formed by curing a composition that includes a compound of Formula 1:

N₃—(R₁)ₘ—N₃ Formula 1

wherein, in Formula 1:

R₁ may be selected from a divalent C₃-C₆₀ carbocyclic group unsubstituted or substituted with at least one R₁₀ₐ, a divalent C₁-C₆₀ heterocyclic group unsubstituted or substituted with at least one R₁₀ₐ, a C₁-C₆₀ alkylene group unsubstituted or substituted with at least one R₁₀ₐ, a C₂-C₆₀ alkenylene group unsubstituted or substituted with at least one R₁₀ₐ, a C₂-C₆₀ alkynylene group unsubstituted or substituted with at least one R₁₀ₐ, —O—, —Si(Q₁)(Q₂)-, —B(Q₁)—, —N(Q₁)-, —P(Q₁)-, —C(═O)—, —S(═O)—, —S(═O)₂—, —P(═O)Q₁-, —P(═S)Q₁-, or a combination thereof, and may be an integer from 1 to 10;

R₁₀ₐ may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),

wherein Q₁, Q₂, Q₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, the compound of Formula 1 may be at least one of the compounds 301 to 303.

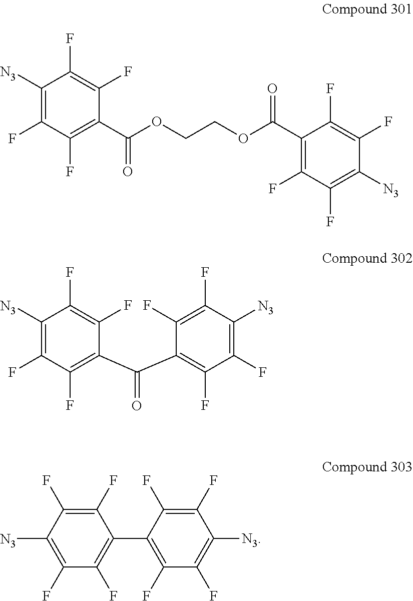 [SMILES: [N-]=[N+]=Nc1c(F)c(F)c(C(=O)OCCOC(=O)c2c(F)c(F)c(N=[N+]=[N-])c(F)c2F)c(F)c1F ; [N-]=[N+]=Nc1c(F)c(F)c(C(=O)c2c(F)c(F)c(N=[N+]=[N-])c(F)c2F)c(F)c1F ; [N-]=[N+]=Nc1c(F)c(F)c(-c2c(F)c(F)c(N=[N+]=[N-])c(F)c2F)c(F)c1F]

For example, a layer formed by curing a composition including a composition of Formula 1 may include an emission layer and/or an electron transport layer.

### Emission Layer in Interlayer 130

When the light-emitting device 10 is a full-color light-emitting device, the emission layer may be patterned into a red emission layer, a green emission layer, and/or a blue emission layer, to provide sub-pixels. In one or more embodiments, the emission layer may have a stacked structure of two or more layers of a red emission layer, a green emission layer, or a blue emission layer, in which the two or more layers contact each other or are separated by layer disposed between the two or more layers to emit white light. In one or more embodiments, the emission layer may include two or more materials of a red light-emitting material, a green light-emitting material, or a blue light-emitting material, in which the two or more materials are mixed with the other in a single layer to emit white light.

The emission layer 130 may include a quantum dot.

A thickness of the emission layer may be in a range of about 100 angstroms (Å) to about 1,000 Å, for example, about 200 Å to about 600 Å. When the thickness of the emission layer is within these ranges, excellent light-emission characteristics may be obtained without a substantial increase in driving voltage.

In an embodiment, the emission layer may be formed by curing the composition including the compound of Formula 1.

### Quantum Dot

The term “quantum dots” as used herein refers to crystals of a semiconductor compound, and may include any material capable of emitting light of various emission wavelengths according to the size of the crystals.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any process similar thereto.

The wet chemical process is a method including mixing a precursor material with an organic solvent and then growing a quantum dot particle crystal in the solution. When the crystal grows, the organic solvent naturally may act as a dispersant coordinated to the surface of the quantum dot crystal. The solvent can help control the growth of the crystal so that the growth of quantum dot particles can be obtained at lower costs, and provide less complex preparation steps and equipment than growing crystals under vapor deposition methods, such as metal organic chemical vapor deposition (MOCVD) or molecular beam epitaxy (MBE),

The quantum dot may include Group II-VI semiconductor compounds, Group III-V semiconductor compounds, Group III-VI semiconductor compounds, Group I-III-VI semiconductor compounds, Group IV-VI semiconductor compounds, a Group IV element or compound, or any combination thereof.

Examples of the Group II-VI semiconductor compound are a binary compound, such as CdS, CdSe, CdTe, ZnS, ZnSe, ZnTe, ZnO, HgS, HgSe, HgTe, MgSe, or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound, such as CdZnSeS, CdZnSeTe, CdZnSTe, CdHgSeS, CdHgSeTe, CdHgSTe, HgZnSeS, HgZnSeTe, or HgZnSTe; or any combination thereof.

Examples of the group III-V semiconductor compound may include a binary compound such as GaN, GaP, GaAs, GaSb, AlN, AlP, AlAs, AlSb, InN, InP, InAs, or InSb; a ternary compound such as GaNP, GaNAs, GaNSb, GaPAs, GaPSb, AlNP, AlNAs, AlNSb, AlPAs, AlPSb, InGaP, InNP, InAlP, InNAs, InNSb, InPAs, or InPSb; a quaternary compound such as GaAlNP, GaAlNAs, GaAlNSb, GaAlPAs, GaAlPSb, GaInNP, GaInNAs, GalnNSb, GaInPAs, GalnPSb, InAlNP, InAlNAs, InAlNSb, InAlPAs, or InAlPSb; or any combination thereof. The Group III-V semiconductor compound may further include a Group II element. Examples of the Group III-V semiconductor compound further including a Group II element are InZnP, InGaZnP, InAlZnP, etc.

Examples of the Group III-VI semiconductor compound are: a binary compound, such as GaS, GaSe, Ga₂Se₃, GaTe, InS, InSe, In₂S₃, In₂Se₃, or InTe; a ternary compound, such as InGaS₃, or InGaSe₃; and any combination thereof.

Examples of the Group I-III-VI semiconductor compound are: a ternary compound, such as AgInS, AgInS₂, CuInS, CuInS₂, CuGaO₂, AgGaO₂, or AgAlO₂; or any combination thereof.

Examples of the Group IV-VI semiconductor compound are: a binary compound, such as SnS, SnSe, SnTe, PbS, PbSe, or PbTe; a ternary compound, such as SnSeS, SnSeTe, SnSTe, PbSeS, PbSeTe, PbSTe, SnPbS, SnPbSe, or SnPbTe; a quaternary compound, such as SnPbSSe, SnPbSeTe, or SnPbSTe; or any combination thereof.

The Group IV element or compound may include: a single element compound, such as Si or Ge; a binary compound, such as SiC or SiGe; or any combination thereof.

Each element included in a multi-element compound such as the binary compound, the ternary compound, and the quaternary compound may be present at a uniform concentration or non-uniform concentration in a particle.

Meanwhile, the quantum dot may have a single structure in which the concentration of each element in the quantum dot is uniform, or a core-shell dual structure. The material included in the core and the material included in the shell may be different from each other.

The shell of the quantum dot may act as a protective layer that prevents chemical degeneration of the core to maintain the desired semiconductor characteristics over time, and/or as a charging layer that imparts electrophoretic characteristics to the quantum dot. The shell may be a single layer or a multi-layer. The interface between the core and the shell may include a concentration gradient in which the concentration of an element existing in the shell increases or decreases toward the center of the core.

Examples of the shell of the quantum dot may be an oxide of metal, metalloid, or non-metal, a semiconductor compound, and any combination thereof. Examples of the oxide of metal, metalloid, or non-metal are a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; a ternary compound, such as MgAl₂O₄, CoFe₂O₄, NiFe₂O₄, or CoMn₂O₄; and any combination thereof. Examples of the semiconductor compound are, as described herein, a Group II-VI semiconductor compound; a Group III-V semiconductor compound; a Group III-VI semiconductor compound; a Group I-III-VI semiconductor compound; a Group IV-VI semiconductor compound; and any combination thereof. For example, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

A full width at half maximum (FWHM) of the emission wavelength spectrum of the quantum dot may be about 45 nm or less, for example, about 40 nm or less, for example, about 30 nm or less, and within these ranges, color purity or color reproducibility may be increased. In addition, because the light emitted through the quantum dot is emitted in all directions, the wide viewing angle may be improved.

In addition, the quantum dot may be in the form of a spherical particle, a pyramidal particle, a multi-arm particle, a cubic nanoparticle, a nanotube particle, a nanowire particle, a nanofiber particle, or a nanoplate particle.

Since the energy band gap may be adjusted by controlling the size of the quantum dot, light having various wavelength bands may be obtained from the quantum dot emission layer. Accordingly, by using quantum dots of different sizes, a light-emitting device that emits light of various wavelengths may be obtained. In one or more embodiments, the size of the quantum dot may be selected to emit red, green and/or blue light. In addition, the size of the quantum dot may be configured to emit white light by the combination of light of various colors.

### Hole Transport Region in Interlayer 130

The hole transport region may have i) a single-layered structure including or consisting of a single layer of a single material, ii) a single-layered structure including or consisting of a single layer including of a plurality of different materials, or iii) a multi-layered structure including a plurality of layers including different materials.

The hole transport region may include a hole injection layer.

The hole injection layer may include graphene, and may, for example, include graphene, consist essentially of graphene, or consist of graphene.

The graphene may be pure graphene.

The graphene has a structure in which carbon atoms are gathered to form a two-dimensional plane. Each of the carbon atoms forms a hexagonal grid and carbon atoms are located at vertices of the hexagon. Such a formation is also called a honeycomb structure or a honeycomb lattice. The thickness of one graphene layer is about 0.2 nm, which is very thin and has high physical and chemical stability. The graphene has very high hole mobility and thermal conductivity and has more than 200 times the strength of steel.

In an embodiment, the thickness of the hole injection layer may be in a range of about 0.2 nm to about 200 nm.

Considering the thickness of one graphene layer, the thickness may not be less than 0.2 nm. If the thickness of the hole injection layer exceeds 200 nm, the desired hole injection characteristics may decrease. The hole injection layer including graphene may physically block the residual solvent or outgassing component in the device. Therefore, oxidation of the electrode (e.g., anode) in contact with the hole injection layer may be prevented or minimized. As a result, device efficiency and lifespan may be improved.

The hole injection layer including graphene may be formed by, for example, a dry process such as a vapor deposition process.

In an embodiment, the hole transport region located between the second electrode (e.g., anode) and the emission layer may include a hole transport layer, an electron blocking layer, or any combination thereof.

For example, the hole transport region may have a multi-layered structure, such as a hole injection layer/hole transport layer structure or a hole injection layer/hole transport layer/electron blocking layer structure, wherein constituent layers for each structure are sequentially stacked in this stated order from the second electrode 150.

In an embodiment, the hole transport layer may include a metal oxide and/or an organic material.

In an embodiment, the hole transport layer may include an oxide of W, Ni, Mo, Cu, V, or any combination thereof.

For example, the hole transport layer may include a compound represented by Formula 30:

M″ₓO_{y} Formula 30

wherein, in Formula 30, M″ may include W, Ni, Mo, Cu, V, or any combination thereof, and x and y may each independently be an integer from 1 to 5.

For example, the hole transport layer may include NiO, WO₃, MoO₃, VO, VO₂, V₂O₃, V₂O₅, V₆O₁₃, Cu₂O, CuO, or any combination thereof.

In an embodiment, the hole transport layer may include a compound including at least one of the following moieties 1 to 11, wherein a point of attachment of the compound to the moiety is at any substitutable atom of the moiety, and each moiety is independently substituted or unsubstituted.

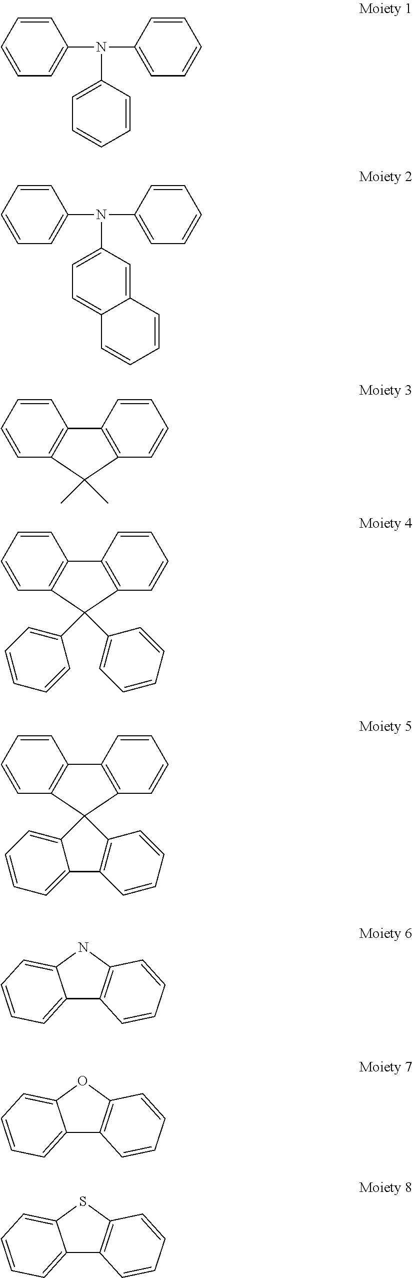

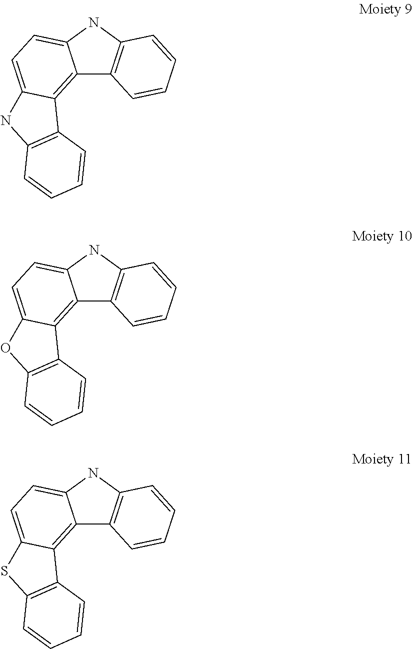 [SMILES: c1ccc2c(c1)[nH]c1ccc3[nH]c4ccccc4c3c12 ; c1ccc2c(c1)[nH]c1ccc3oc4ccccc4c3c12 ; c1ccc2c(c1)[nH]c1ccc3sc4ccccc4c3c12]

In an embodiment, the moieties 5 and 8-10, the moiety may be connected to the compound through the ring nitrogen or a ring carbon.

In an embodiment, the hole transport layer may include one of the following compounds:

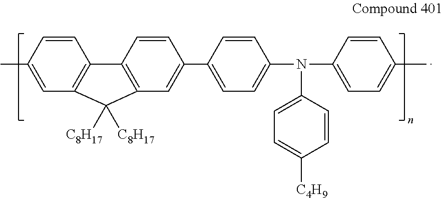

wherein, in Compound 401, n2 is an integer from 2 to 300, or Compound 402

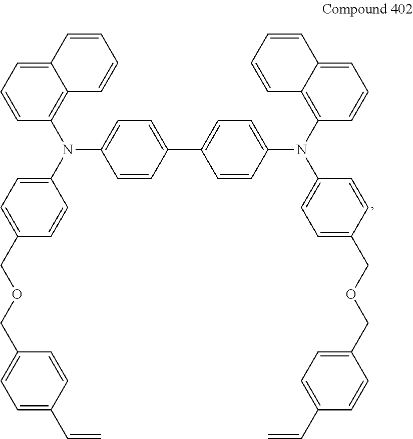 [SMILES: C=Cc1ccc(COCc2ccc(N(c3ccc(-c4ccc(N(c5ccc(COCc6ccc(C=C)cc6)cc5)c5cccc6ccccc56)cc4)cc3)c3cccc4ccccc34)cc2)cc1]

or a combination thereof.

For example, the hole transport layer may include an oxide of W, Ni, Mo, Cu, V, or any combination thereof, and/or may include a compound including one of Moieties 1 to 11.

### Second Electrode 150

The second electrode 150 may be located on the interlayer 130 having a structure as described above. The second electrode 150 may be an anode, and may be a semi-transmissive electrode, a transmissive electrode, or a reflective electrode.

When the second electrode 150 is a transmissive electrode, a material for forming the second electrode 150 may be ITO, IZO, SnO₂, ZnO, or any combinations thereof. In one or more embodiments, when the second electrode 150 is a semi-transmissive electrode or a reflective electrode, a material for forming the second electrode 150 may include Mg, Ag, Al, aluminum-lithium (Al—Li), Ca, magnesium-indium (Mg—In), magnesium-silver (Mg—Ag), or any combination thereof.

The second electrode 150 may have a single-layered structure having a single layer, or a multi-layered structure including a plurality of layers.

### Capping Layer

A first capping layer may be located outside, e.g., proximate to an external surface, of the first electrode 110, and/or a second capping layer may be located outside, e.g., proximate to an external surface of the second electrode 150. In particular, the light-emitting device 10 may have a structure in which the first capping layer, the first electrode 110, the interlayer 130, and the second electrode 150 are sequentially stacked in the stated order, a structure in which the first electrode 110, the interlayer 130, the second electrode 150, and the second capping layer are sequentially stacked in the stated order, or a structure in which the first capping layer, the first electrode 110, the interlayer 130, the second electrode 150, and the second capping layer are sequentially stacked in the stated order.

In an embodiment, light generated by the emission layer in the interlayer 130 of the light-emitting device 10 may be extracted or directed to the outside through the second electrode 150, which is a semi-transmissive electrode or a transmissive electrode, and the second capping layer.

The first capping layer and the second capping layer may increase external emission efficiency according to the principle of constructive interference. Accordingly, the light extraction efficiency of the light-emitting device 10 is increased, so that the luminescence efficiency of the light-emitting device 10 may be improved.

Each of the first capping layer and the second capping layer may include a material having a refractive index (at 589 nm) of about 1.5 to about 2.0 (for example, a refractive index (at 589 nm) of about 1.6 or more).

The first capping layer and the second capping layer may each independently be an organic capping layer including an organic material, an inorganic capping layer including an inorganic material, or a composite capping layer including an organic material and an inorganic material.

At least one of the first capping layer and the second capping layer may each independently include carbocyclic compounds, heterocyclic compounds, amine group-containing compounds, porphine derivatives, phthalocyanine derivatives, naphthalocyanine derivatives, alkali metal complexes, alkaline earth metal complexes, or any combination thereof. Optionally, the carbocyclic compound, the heterocyclic compound, and the amine group-containing compound may be substituted with a substituent including O, N, S, Se, Si, F, Cl, Br, I, or any combination thereof. In one or more embodiments, at least one of the first capping layer and the second capping layer may each independently include an amine group-containing compound.

For example, at least one of the first capping layer and the second capping layer may each independently include: one of Compounds CP1 to CP6; β-NPB; or any compound thereof:

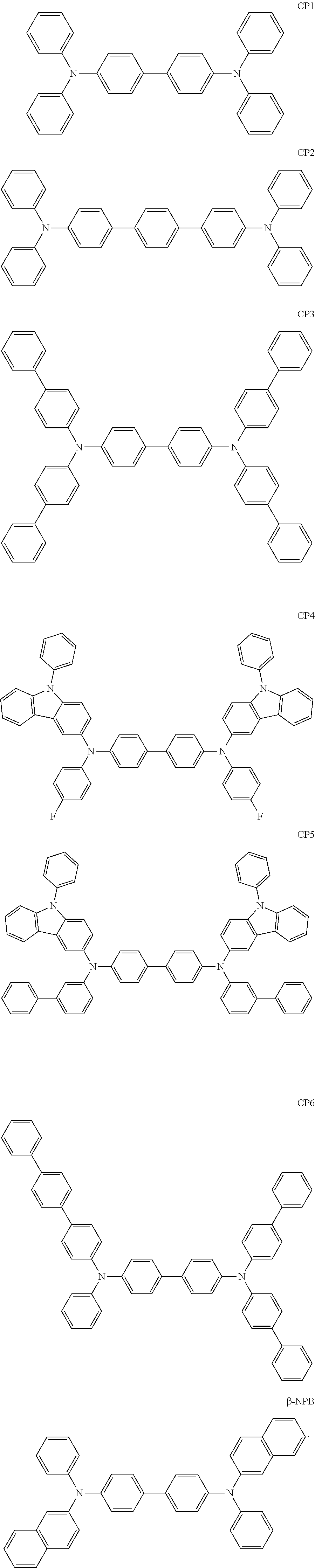

### Electronic Apparatus

The light-emitting device may be included in various electronic apparatuses. For example, the electronic apparatus including the light-emitting device may be a light-emitting apparatus, an authentication apparatus, or the like.

The electronic apparatus (for example, a light-emitting apparatus) may further include, in addition to the light-emitting device, i) a color filter, ii) a color conversion layer, or iii) a color filter and a color conversion layer. The color filter and/or the color conversion layer may be located in at least one direction in which light emitted from the light-emitting device travels or is directed. For example, the light emitted from the light-emitting device may be blue light or white light. For details on the light-emitting device, related description provided above may be referred to. In one or more embodiments, the color conversion layer may include a quantum dot. The quantum dot may be, for example, a quantum dot as described herein.

The electronic apparatus may include a first substrate. The first substrate may include a plurality of subpixel areas, the color filter may include a plurality of color filter areas respectively corresponding to the subpixel areas, and the color conversion layer may include a plurality of color conversion areas respectively corresponding to the subpixel areas.

A pixel-defining film may be located among the subpixel areas to define each of the subpixel areas.

The color filter may further include a plurality of color filter areas and light-shielding patterns located among the color filter areas, and the color conversion layer may further include a plurality of color conversion areas and light-shielding patterns located among the color conversion areas.

The plurality of color filter areas (or the plurality of color conversion areas) may include a first area emitting first color light, a second area emitting second color light, and/or a third area emitting third color light, wherein the first color light, the second color light, and/or the third color light may have different maximum emission wavelengths from one another. For example, the first color light may be red light, the second color light may be green light, and the third color light may be blue light. For example, the plurality of color filter areas (or the plurality of color conversion areas) may include quantum dots. In particular, the first area may include a red quantum dot, the second area may include a green quantum dot, and the third area may not include a quantum dot. For details on the quantum dot, related descriptions provided herein may be referred to. The first area, the second area, and/or the third area may each include a scatterer.

For example, the light-emitting device may emit first light, the first area may absorb the first light to emit first-first color light, the second area may absorb the first light to emit second-first color light, and the third area may absorb the first light to emit third-first color light. In this regard, the first-first color light, the second-first color light, and the third-first color light may have different maximum emission wavelengths. In particular, the first light may be blue light, the first-first color light may be red light, the second-first color light may be green light, and the third-first color light may be blue light.

The electronic apparatus may further include a thin-film transistor, in addition to the light-emitting device as described above. The thin-film transistor may include a source electrode, a drain electrode, and an activation layer, wherein any one of the source electrode and the drain electrode may be electrically connected to any one of the first electrode and the second electrode of the light-emitting device.

The thin-film transistor may further include a gate electrode, a gate insulating film, or the like.

The activation layer may include crystalline silicon, amorphous silicon, an organic semiconductor, an oxide semiconductor, or the like.

The electronic apparatus may further include a sealing portion for sealing the light-emitting device. The sealing portion may be located between the color filter and/or the color conversion layer and the light-emitting device. The sealing portion allows light from the light-emitting device to be extracted to the outside, and simultaneously prevents ambient air and moisture from penetrating into the light-emitting device. The sealing portion may be a sealing substrate including a transparent glass substrate or a plastic substrate. The sealing portion may be a thin-film encapsulation layer including at least one layer of an organic layer and/or an inorganic layer. When the sealing portion is a thin film encapsulation layer, the electronic apparatus may be flexible.

Various functional layers may be additionally located on the sealing portion, in addition to the color filter and/or the color conversion layer, according to the use of the electronic apparatus. Examples of the functional layers may include a touch screen layer, a polarizing layer, and the like. The touch screen layer may be a pressure-sensitive touch screen layer, a capacitive touch screen layer, or an infrared touch screen layer.

The authentication apparatus may be, for example, a biometric authentication apparatus that authenticates an individual by using biometric information of a living body (for example, fingertips, pupils, etc.).

The authentication apparatus may further include, in addition to the light-emitting device as described above, a biometric information collector.

The electronic apparatus may be applied to various displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

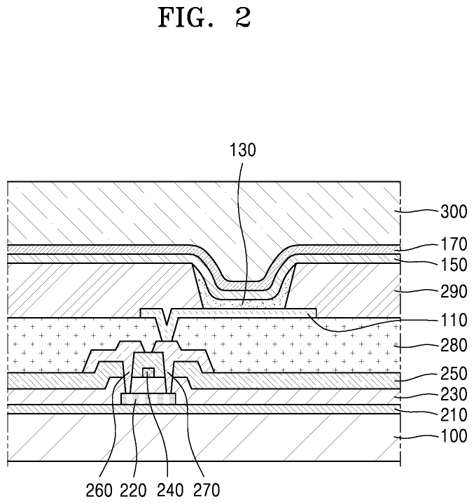

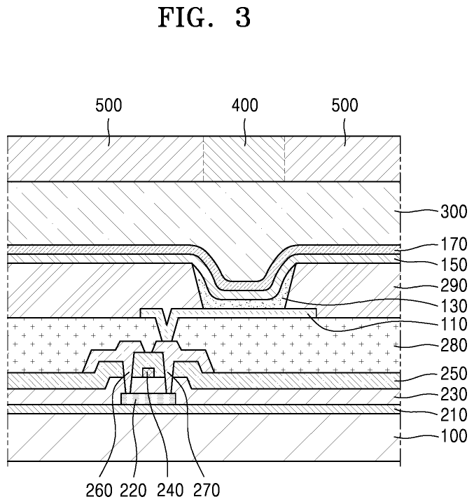

### Description of FIGS. 2 and 3

In an embodiment, an electronic apparatus may include the light-emitting device.

In an embodiment, the electronic apparatus may further include a thin-film transistor, where the thin-film transistor includes a source electrode and a drain electrode, and the first electrode of the light-emitting device may be electrically connected to at least one of the source and drain electrodes of the thin-film transistor.

In an embodiment, the TFT may be an oxide TFT. The oxide TFT may include, for example, an N-channel metal oxide semiconductor (NMOS). NMOS has lower hysteresis than that of a P-channel metal oxide semiconductor (PMOS).

In an embodiment, in the oxide-based TFT, a major carrier is an electron, and electron mobility is relatively high. In addition, the oxide-based TFT is good for a low-temperature process and a large area and is similar to a a-Si TFT. Also, because a leakage current is small, the capacitance may be maintained, and thus, driving of the device is stable even at a low current.

In an embodiment, the electronic apparatus may further include a color filter, a color conversion layer, a touch screen layer, a polarizing layer, or any combination thereof.

In an embodiment, a capping layer may be disposed outside the first electrode and/or the second electrode.

FIG. 2 is a cross-sectional view of an electronic apparatus according to an embodiment.

The electronic apparatus of FIG. 2 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be located on the substrate 100. The buffer layer 210 may prevent penetration of impurities through the substrate 100 and may provide a flat surface on the substrate 100.

A TFT may be located on the buffer layer 210. The TFT may include an activation layer 220, a gate electrode 240, a source electrode 260, and a drain electrode 270.

The activation layer 220 may include an inorganic semiconductor such as silicon or polysilicon, an organic semiconductor, or an oxide semiconductor, and may include a source region, a drain region, and a channel region.

A gate insulating film 230 for insulating the activation layer 220 from the gate electrode 240 may be located on the activation layer 220, and the gate electrode 240 may be located on the gate insulating film 230.

An interlayer insulating film 250 may be located on the gate electrode 240. The interlayer insulating film 250 may be located between the gate electrode 240 and the source electrode 260 and between the gate electrode 240 and the drain electrode 270, to insulate from one another.

The source electrode 260 and the drain electrode 270 may be located on the interlayer insulating film 250. The interlayer insulating film 250 and the gate insulating film 230 may be formed to expose the source region and the drain region of the activation layer 220, and the source electrode 260 and the drain electrode 270 may be located in contact with the exposed portions of the source region and the drain region of the activation layer 220.

The TFT is electrically connected to a light-emitting device to drive the light-emitting device, and is covered and protected by a passivation layer 280. The passivation layer 280 may include an inorganic insulating film, an organic insulating film, or any combination thereof. A light-emitting device is provided on the passivation layer 280. The light-emitting device may include a first electrode 110, an interlayer 130, and a second electrode 150.

The first electrode 110 may be located on the passivation layer 280. The passivation layer 280 may be located to expose a portion of the drain electrode 270, not fully covering the drain electrode 270, and the first electrode 110 may be located to be connected to the exposed portion of the drain electrode 270.

A pixel defining layer 290 including an insulating material may be located on the first electrode 110. The pixel defining layer 290 may expose a certain region of the first electrode 110, and an interlayer 130 may be formed in the exposed region of the first electrode 110. The pixel defining layer 290 may be a polyimide or polyacrylic organic film. Although not shown in FIG. 2, at least some layers (for example, the electron transport layer) in the interlayer 130 may extend beyond the upper portion of the pixel-defining film 290 to be located in the form of a common layer.

The second electrode 150 may be located on the interlayer 130, and a capping layer 170 may be additionally formed on the second electrode 150. The capping layer 170 may be formed to cover the second electrode 150.

The encapsulation portion 300 may be located on the capping layer 170. The encapsulation portion 300 may be located on a light-emitting device to protect the light-emitting device from moisture or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE), or the like), or any combination thereof; or any combination of the inorganic films and the organic films.

FIG. 3 is a cross-sectional view of an electronic apparatus according to another embodiment of the present disclosure.

The electronic apparatus of FIG. 3 is the same as the light-emitting apparatus of FIG. 2, except that a light-shielding pattern 500 and a functional region 400 are additionally located on the encapsulation portion 300. The functional region 400 may be i) a color filter area, ii) a color conversion area, or iii) a combination of the color filter area and the color conversion area. In an embodiment, the light-emitting device included in the light-emitting apparatus of FIG. 3 may be a tandem light-emitting device.

### Manufacturing Method

Respective layers included in the hole transport region, the emission layer, and respective layers included in the electron transport region may be formed in a certain region by using one or more suitable methods selected from vacuum deposition, spin coating, casting, Langmuir-Blodgett (LB) deposition, ink-jet printing, laser-printing, and laser-induced thermal imaging.

In an embodiment, the electron injection layer, the electron transport layer, the emission layer, the hole transport layer, and the electron injection layer may all be layers formed by a solution process. The solution process may include, for example, a spin coating method, an inkjet process, or the like.

When forming an electron injection layer, an electron transport layer, an emission layer, a hole transport layer, and a hole injection layer through a solution process, the electron injection layer may use an electron injection layer composition including an oxide of Zn, Ti, Zr, Sn, Mg, Co, Ni, Mn, Y, Al, or any combination thereof, the electron transport layer may use an electron transport layer composition including a phosphine oxide compound, and the emission layer may include an emission layer composition including a quantum dot.

In an embodiment, the ETL composition and/or the EML composition may further include the compound of Formula 1. The electron transport layer and/or the emission layer may be formed by applying the ETL composition including the compound of Formula 1 and/or the EML composition including the compound of Formula 1 by the solution process, and then by curing with heat or light.

In the ETL composition, an amount of the compound of Formula 1 may be in a range of about 0.1 wt % to about 30 wt % based on 100 wt % of the phosphine oxide compound.

In the EML composition, an amount of the compound of Formula 1 may be in a range of about 0.1 wt % to about 30 wt % based on 100 wt % of the quantum dot.

When the amount of the compound of Formula 1 is within the ranges above in the compositions, the light-emitting device may have excellent efficiency and lifespan.

The compositions may include a solvent. The solvent may include, for example, a compound, such as alcohols, ethers, alkane hydrocarbons, substituted or unsubstituted aromatic hydrocarbons, and the like. The compositions may further include, for example, a dispersant as needed. The dispersant may include anionic, cationic, and nonionic polymeric materials.

Regarding a concentration of one or more material components in the compositions, the compositions may have a concentration suitable for the solution process. For example, a concentration of each material component of the compositions may independently be in a range of about 0.1 wt % to about 20 wt %, or about 0.1 wt % to about 5 wt %, based on 100 wt % of each of the composition.

When layers constituting the hole transport region, an emission layer, and layers constituting the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on a material to be included in a layer to be formed and the structure of a layer to be formed.

In the case of using an inkjet, an inkjet printer used for the inkjet may be a known inkjet printer in the art.

When each of the electron injection layer, the electron transport layer, the emission layer, and the hole injection layer is formed by spin coating, the spin coating may be performed at a coating speed of about 2,000 rpm to about 5,000 rpm and at a heat treatment temperature of about 80° C. to 200° C. depending on a material to be included in a layer to be formed and the structure of a layer to be formed.

### Definition of Terms

As used herein, when a definition is not otherwise provided, “substituted” refers to replacement of at least one hydrogen of a moiety, e.g., moiety 1 to 11, by

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),

wherein Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each substituted with deuterium, —F, a cyano group, a C₁-C₆₀ alkyl group, a C₁-C₆₀ alkoxy group, a phenyl group, a biphenyl group, or any combination thereof.

The term “C₃-C₆₀ carbocyclic group” as used herein refers to a cyclic group consisting of carbon only as a ring-forming atom and having three to sixty carbon atoms, and the term “C₁-C₆₀ heterocyclic group” as used herein refers to a cyclic group that has one to sixty carbon atoms and further has, in addition to carbon, a heteroatom as a ring-forming atom. The C₃-C₆₀ carbocyclic group and the C₁-C₆₀ heterocyclic group may each be a monocyclic group consisting of one ring (aromatic or non-aromatic) or a polycyclic group in which two or more rings (independently aromatic or non-aromatic) are condensed with each other. For example, the C₁-C₆₀ heterocyclic group has 3 to 61 ring-forming atoms.

The “cyclic group” as used herein may include the C₃-C₆₀ carbocyclic group, and the C₁-C₆₀ heterocyclic group.

The term “π electron-rich C₃-C₆₀ cyclic group” as used herein refers to a cyclic group that has three to sixty carbon atoms and does not include *—N═*′ as a ring-forming moiety, and the term “π electron-deficient nitrogen-containing C₁-C₆₀ cyclic group” as used herein refers to a heterocyclic group that has one to sixty carbon atoms and includes *—N═*′ as a ring-forming moiety.

For example,

the C₃-C₆₀ carbocyclic group may be i) a group T1 or ii) a condensed cyclic group in which two or more groups T1 are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

the C₁-C₆₀ heterocyclic group may be i) a group T2, ii) a condensed cyclic group in which two or more groups T2 are condensed with each other, or iii) a condensed cyclic group in which at least one group T2 and at least one group T1 are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

the π electron-rich C₃-C₆₀ cyclic group may be i) a group T1, ii) a condensed cyclic group in which two or more groups T1 are condensed with each other, iii) a group T3, iv) a condensed cyclic group in which two or more groups T3 are condensed with each other, or v) a condensed cyclic group in which at least one group T3 and at least one group T1 are condensed with each other (for example, the C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, etc.),

the π electron-deficient nitrogen-containing C₁-C₆₀ cyclic group may be i) a group T4, ii) a condensed cyclic group in which two or more groups T4 are condensed with each other, iii) a condensed cyclic group in which at least one group T4 and at least one group T1 are condensed with each other, iv) a condensed cyclic group in which at least one group T4 and at least one group T3 are condensed with each other, or v) a condensed cyclic group in which at least one group T4, at least one group T1, and at least one group T3 are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, etc.),

the group T1 may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or a bicyclo[2.2.1]heptane) group, a norbornene group, a bicyclo[1.1.1]pentane group, a bicyclo[2.1.1]hexane group, a bicyclo[2.2.2]octane group, or a benzene group, the group T2 may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

the group T3 may be a furan group, a thiophene group, a 1H-pyrrole group, a silole group, or a borole group, and

the group T4 may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “the cyclic group, the C₃-C₆₀ carbocyclic group, the C₁-C₆₀ heterocyclic group, the π electron-rich C₃-C₆₀ cyclic group, or the π electron-deficient nitrogen-containing C₁-C₆₀ cyclic group” as used herein refer to a group (aromatic or non-aromatic) condensed to any cyclic group, a monovalent group, or a polyvalent group (for example, a divalent group, a trivalent group, a tetravalent group, etc.) according to the structure of a formula for which the corresponding term is used. For example, the “benzene group” may be a benzo group, a phenyl group, a phenylene group, or the like, which may be easily understood by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the divalent C₁-C₆₀ heterocyclic group may include a C₃-C₁ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein refers to a linear or branched aliphatic hydrocarbon monovalent group that has one to sixty carbon atoms, and specific examples thereof are a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein refers to a divalent group having the same structure as the C₁-C₆₀ alkyl group.

The term “C₂-C₆₀ alkenyl group” as used herein refers to a monovalent hydrocarbon group having at least one carbon-carbon double bond in the middle or at the terminus of the C₂-C₆₀ alkyl group, and examples thereof are an ethenyl group, a propenyl group, and a butenyl group. The term “C₂-C₆₀ alkenylene group” as used herein refers to a divalent group having the same structure as the C₂-C₆₀ alkenyl group.

The term “C₂-C₆₀ alkynyl group” as used herein refers to a monovalent hydrocarbon group having at least one carbon-carbon triple bond in the middle or at the terminus of the C₂-C₆₀ alkyl group, and examples thereof include an ethynyl group, a propynyl group, and the like. The term “C₂-C₆₀ alkynylene group” as used herein refers to a divalent group having the same structure as the C₂-C₆₀ alkynyl group.

The term “C₁-C₆₀ alkoxy group” as used herein refers to a monovalent group represented by —OA₁₀₁ (wherein A₁₀₁ is the C₁-C₆₀ alkyl group), and examples thereof include a methoxy group, an ethoxy group, and an isopropyloxy group.

The term “C₃-C₁₀ cycloalkyl group” as used herein refers to a monovalent saturated hydrocarbon cyclic group having 3 to 10 carbon atoms, and examples thereof are a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, and a bicyclo[2.2.2]octyl group. The term “C₃-C₁₀ cycloalkylene group” as used herein refers to a divalent group having the same structure as the C₃-C₁₀ cycloalkyl group.

The term “C₁-C₁ heterocycloalkyl group” as used herein refers to a monovalent cyclic group of 1 to 10 carbon atoms, further including, in addition to carbon atoms, at least one heteroatom, as ring-forming atoms, and specific examples are a 1,2,3,4-oxatriazolidinyl group, a tetrahydrofuranyl group, and a tetrahydrothiophenyl group. The term “C₁-C₁₀ heterocycloalkylene group” as used herein refers to a divalent group having the same structure as the C₁-C₁₀ heterocycloalkyl group.

The term “C₃-C₁₀ cycloalkenyl group” used herein refers to a monovalent cyclic group that has three to ten carbon atoms and at least one carbon-carbon double bond in the ring thereof and no aromaticity, and specific examples thereof are a cyclopentenyl group, a cyclohexenyl group, and a cycloheptenyl group. The term “C₃-C₁₀ cycloalkenylene group” as used herein refers to a divalent group having the same structure as the C₃-C₁₀ cycloalkenyl group.

The term “C₁-C₁₀ heterocycloalkenyl group” as used herein refers to a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁₀ heterocycloalkenyl group include a 4,5-dihydro-1,2,3,4-oxatriazolyl group, a 2,3-dihydrofuranyl group, and a 2,3-dihydrothiophenyl group. The term “C₁-C₁₀ heterocycloalkenylene group” as used herein refers to a divalent group having the same structure as the C₁-C₁₀ heterocycloalkenyl group.

The term “C₆-C₆₀ aryl group” as used herein refers to a monovalent group having a carbocyclic aromatic system of 6 to 60 carbon atoms, and the term “C₆-C₆₀ arylene group” as used herein refers to a divalent group having a carbocyclic aromatic system of 6 to 60 carbon atoms. Examples of the C₆-C₆₀ aryl group are a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, and an ovalenyl group. When the C₆-C₆₀ aryl group and the C₆-C₆₀ arylene group each include two or more rings, the rings may be condensed with each other.

The term “C₁-C₆₀ heteroaryl group” as used herein refers to a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein refers to a divalent group having a heterocyclic aromatic system of 1 to 60 carbon atoms, further including, in addition to carbon atoms, at least one heteroatom, as ring-forming atoms. Examples of the C₁-C₆₀ heteroaryl group are a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the rings may be condensed with each other.

The term “monovalent non-aromatic condensed polycyclic group” as used herein refers to a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group are an indenyl group, a fluorenyl group, a spiro-bifluorenyl group, a benzofluorenyl group, an indenophenanthrenyl group, and an indeno anthracenyl group. The term “divalent non-aromatic condensed polycyclic group” as used herein refers to a divalent group having the same structure as the monovalent non-aromatic condensed polycyclic group described above.

The term “monovalent non-aromatic condensed heteropolycyclic group” as used herein refers to a monovalent group (for example, having 1 to 60 carbon atoms) having two or more rings condensed to each other, further including, in addition to carbon atoms, at least one heteroatom, as ring-forming atoms, and having non-aromaticity in its entire molecular structure. Examples of the monovalent non-aromatic condensed heteropolycyclic group include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, and a benzothienodibenzothiophenyl group. The term “divalent non-aromatic condensed heteropolycyclic group” as used herein refers to a divalent group having the same structure as the monovalent non-aromatic condensed heteropolycyclic group described above.

The term “C₆-C₆₀ aryloxy group” as used herein indicates —OA₁₀₂ (wherein A₁₀₂ is the C₆-C₆₀ aryl group), and the term “C₆-C₆₀ arylthio group” as used herein indicates —SA₁₀₃ (wherein A₁₀₃ is the C₆-C₆₀ aryl group).

The term “C₇-C₆₀ arylalkyl group” used herein refers to -A₁₀₄A₁₀₅ (where A₁₀₄ may be a C₁-C₅₄ alkylene group, and A₁₀₅ may be a C₆-C₅₉ aryl group), and the term C₂-C₆₀ heteroarylalkyl group” used herein refers to -A₁₀₆A₁₀₇ (where A₁₀₆ may be a C₁-C₅₉ alkylene group, and A₁₀₇ may be a C₁-C₅₉ heteroaryl group).

The term “R₁₀ₐ” as used herein refers to:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),

wherein Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each substituted with deuterium, —F, a cyano group, a C₁-C₆₀ alkyl group, a C₁-C₆₀ alkoxy group, a phenyl group, a biphenyl group, or any combination thereof.

The term “heteroatom” as used herein refers to any atom other than a carbon atom. Examples of the heteroatom are O, S, N, P, Si, B, Ge, Se, and any combinations thereof.

The term “the third-row transition metal” used herein includes hafnium (Hf), tantalum (Ta), tungsten (W), rhenium (Re), osmium (Os), iridium (Ir), platinum (Pt), gold (Au), etc.

“Ph” as used herein refers to a phenyl group, “Me” as used herein refers to a methyl group, “Et” as used herein refers to an ethyl group, “ter-Bu” or “Bu^{t}” as used herein refers to a tert-butyl group, and “OMe” as used herein refers to a methoxy group.

The term “biphenyl group” as used herein refers to “a phenyl group substituted with a phenyl group.” In other words, the “biphenyl group” is a substituted phenyl group having a C₆-C₆₀ aryl group as a substituent.

The term “terphenyl group” as used herein refers to “a phenyl group substituted with a biphenyl group.” In other words, the “terphenyl group” is a substituted phenyl group having, as a substituent, a C₆-C₆₀ aryl group substituted with a C₆-C₆₀ aryl group.

The maximum number of carbon atoms in this substituent definition section is an example only. In an embodiment, the maximum carbon number of 60 in the C₁-C₆₀ alkyl group is an example, and the definition of the alkyl group is equally applied to a C₁-C₂₀ alkyl group. The same applies to other cases.

* and *′ as used herein, unless defined otherwise, each refer to a binding site to a neighboring atom in a corresponding formula.

Hereinafter, a light-emitting device according to embodiments will be described in detail with reference to Examples.

### EXAMPLES

### Preparing Composition for Solution Process

For a solution process, compositions were prepared as shown in Table 1.

TABLE 1

| Composition | Solute | Solvent | Total solids (wt %) |
|---|---|---|---|
| EIL-1 | ZnO | Ethanol | 3 |
| EIL-2 | ZnMgO | Ethanol | 3 |
| ETL-1 | Compound 101 | Ethanol | 1 |
| | Compound 201 | | 0.5 wt % |
| | | | Compound 201 |
| | | | 0.5 wt % |
| | | | Compound 101 |
| ETL-2 | Compound 109 | Ethanol | 1 |
| | Compound 201 | | 0.5 wt % |
| | | | Compound 201 |
| | | | 0.5 wt % |
| | | | Compound 109 |
| ETL-3 | Compound 101 | Ethanol | 1 |
| | Compound 202 | | 0.5 wt % |
| | | | Compound 202 |
| | | | 0.5 wt % |
| | | | Compound 101 |
| ETL-4 | Compound 109 | Ethanol | 1 |
| | Compound 202 | | 0.5 wt % |
| | | | Compound 202 |
| | | | 0.5 wt % |
| | | | Compound 109 |
| ETL-5 | Compound 101 | Ethanol | 1 |
| | Compound 209 | | 0.5 wt % |
| | | | Compound 209 |
| | | | 0.5 wt % |
| | | | Compound 101 |
| ETL-6 | Compound 109 | Ethanol | 1 |
| | Compound 209 | | 0.5 wt % |
| | | | Compound 209 |
| | | | 0.5 wt % |
| | | | Compound 109 |
| ETL-7 | Compound 101 | Ethanol | 1 |
| | Compound 202 | | 0.2 wt % |
| | | | Compound 202 |
| | Compound 303 | | 0.2 wt % |
| | | | Compound 101 |
| | | | 0.6 wt % |
| | | | Compound 303 |
| R EML-1 | InP quantum | Octane | 1 |
| | dot | | |
| R EML-2 | InP quantum | Octane | 1 |
| | dot | | |
| | Compound 303 | | 0.75 wt % |
| | | | Compound 303 |
| | | | 0.25 wt % InP |
| | | | quantum dot |
| HTL-1 | NiO | Ethanol | 3.0 |
| HTL-2 | WO₃ | Ethanol | 3.0 |
| HTL-3 | Compound 401 | Cyclohexylbenzene | 2.5 |
| HTL-4 | Compound 402 | Cyclohexylbenzene | 2.5 |
| HIL-1 | Compound 401 | Cyclohexylbenzene | 2.5 wt % |
| | Compound 501 | | 0.5 wt % |
| | | | Compound 501 |
| | | | 2.0 wt % |
| | | | Compound 401 |

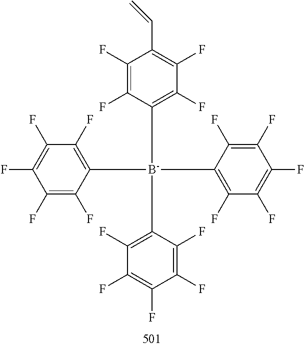 [SMILES: C=Cc1c(F)c(F)c([B-](c2c(F)c(F)c(F)c(F)c2F)(c2c(F)c(F)c(F)c(F)c2F)c2c(F)c(F)c(F)c(F)c2F)c(F)c1F]

A counter ion in Compound 501 is Li⁺.

### Manufacture of Light-Emitting Device

### Example 1

An ITO glass substrate (50×50 mm, 15Ω/□ (“square”)), which is a glass substrate (manufactured by Samsung-Corning) for a quantum dot light-emitting device, was subjected to ultrasonic cleaning sequentially using distilled water and isopropanol, followed by UV ozone cleaning for 30 minutes. Following the cleaning step, the glass substrate with an attached transparent electrode line was spin-coated with EIL-1 to form a film having a thickness of 80 nanometers (nm). Then, a baking process was performed at 120° C. for 10 minutes to form an electron injection layer.

To the electron injection layer, R EML-1 was spin-coated thereon to form a film having a thickness of 20 nm, and a baking process was performed at 100° C. for 10 minutes to form a red emission layer. To the red emission layer, HTL-1 was spin coated thereon to form a film having a thickness of 20 nm, and a baking process was performed at 150° C. for 10 minutes to form a hole transport layer.

A hole injection layer having a thickness of 20 nm was formed by depositing pure graphene on the hole transport layer according to a chemical vapor deposition method.

The resultant glass substrate was loaded on a substrate holder in a vacuum deposition apparatus, and Al was deposited on the hole injection layer to form an anode having a thickness of 100 nm, thereby completing the manufacture of an inverted quantum dot light-emitting device. The equipment used for the deposition was a Suicel plus 200 evaporator from Sunic Systems.

### Example 2

A light-emitting device was manufactured in the same manner as in Example 1, except that EIL-2 was used to form an electron injection layer.

### Example 3

EIL-1 was spin-coated on a substrate described above to form a film having a thickness of 60 nm, and a baking process was performed at 120° C. for 10 minutes to form an electron injection layer. To the electron injection layer, ETL-1 was spin-coated thereon to form a film having a thickness of 20 nm, and a baking process was performed at 120° C. for 10 minutes to form an electron transport layer. The remaining process steps described in Example 1 were then used to complete the light-emitting device of Example 3.

### Examples 4 to 12

Light-emitting devices were manufactured in the same manner as in Example 3, except that an electron injection layer, an electron transport layer, an emission layer, a hole transport layer, and a hole injection layer were formed as provided in Table 2.

### Comparative Examples 1 and 2

Light-emitting devices were manufactured in the same manner as in Example 1, except that an electron injection layer, an emission layer, a hole transport layer, and a hole injection layer were formed as provided in Table 2. Comparative Example 1 does not have a hole injection layer.

### Comparative Examples 3 and 4

Light-emitting devices were manufactured in the same manner as in Example 3, except that an electron injection layer, an electron transport layer, an emission layer, a hole transport layer, and a hole injection layer were formed as provided in Table 2.

TABLE 2

| | Electron | Electron | | Hole | |
|---|---|---|---|---|---|
| | injection | transport | Emission | transport | |
| | layer | layer | layer | layer | Hole injection layer |
| Example 1 | EIL-1 | — | R EML-1 | HTL-1 | pure graphene |
| Example 2 | EIL-2 | — | R EML-1 | HTL-1 | pure graphene |
| Example 3 | EIL-1 | ETL-1 | R EML-1 | HTL-1 | pure graphene |
| Example 4 | EIL-2 | ETL-1 | R EML-1 | HTL-1 | pure graphene |
| Example 5 | EIL-2 | ETL-2 | R EML-1 | HTL-1 | pure graphene |
| Example 6 | EIL-2 | ETL-3 | R EML-1 | HTL-1 | pure graphene |
| Example 7 | EIL-2 | ETL-4 | R EML-1 | HTL-1 | pure graphene |
| Example 8 | EIL-2 | ETL-5 | R EML-1 | HTL-1 | pure graphene |
| Example 9 | EIL-2 | ETL-6 | R EML-1 | HTL-1 | pure graphene |
| Example 10 | EIL-2 | ETL-6 | R EML-1 | HTL-2 | pure graphene |
| Example 11 | EIL-2 | ETL-7 | R EML-1 | HTL-4 | pure graphene |
| Example 12 | EIL-2 | ETL-7 | R EML-1 | HTL-4 | pure graphene |
| Comparative | EIL-2 | — | R EML-1 | HTL-1 | — |
| Example 1 | | | | | |
| Comparative | EIL-2 | — | R EML-1 | HTL-1 | HIL-1 |
| Example 2 | | | | | |
| Comparative | EIL-2 | ETL-1 | R EML-1 | HTL-1 | Graphene oxide |
| Example 3 | | | | | |
| Comparative | EIL-2 | ETL-1 | R EML-1 | HTL-1 | Bromine-doped |
| Example 4 | | | | | graphene |

To evaluate the characteristics of the light-emitting devices manufactured according to Examples and Comparative Examples, the driving voltage at a current density of 10 mA/cm², efficiency, color coordinates, lifespan, and the like were measured, and results are shown in Table 3.

The driving voltage and current density of the light-emitting device were measured by using a source meter (Keithley Instrument Company, 2400 series), the color coordinates were measured with a power supplied from a current-voltage measuring meter (Kethley SMU 236) by using a luminance meter PR650, and the efficiency and lifespan were measured by using a measuring device C9920-2-12 of Hamamaches Company.

TABLE 3

| | Driving | Efficiency | Color coordinate | | Lifespan T90 |
|---|---|---|---|---|---|
| | voltage | [cd/A] | CIEx | CIEy | [hr] |
| Example 1 | 3.0 | 15.8 | 0.68 | 0.32 | 420 |
| Example 2 | 3.8 | 20.4 | 0.68 | 0.32 | 450 |
| Example 3 | 3.8 | 20.8 | 0.68 | 0.32 | 420 |
| Example 4 | 3.8 | 21.5 | 0.68 | 0.32 | 430 |
| Example 5 | 3.6 | 20.8 | 0.68 | 0.32 | 450 |
| Example 6 | 3.2 | 20.5 | 0.68 | 0.32 | 420 |
| Example 7 | 3.0 | 20.2 | 0.68 | 0.32 | 430 |
| Example 8 | 3.2 | 20.4 | 0.68 | 0.32 | 440 |
| Example 9 | 3.6 | 19.5 | 0.68 | 0.32 | 480 |
| Example 10 | 4.2 | 18.8 | 0.68 | 0.32 | 480 |
| Example 11 | 4.4 | 21.8 | 0.68 | 0.32 | 500 |
| Example 12 | 4.2 | 22.7 | 0.68 | 0.32 | 550 |
| Comparative | 9.8 | 2.9 | 0.65 | 0.36 | 10 |
| Example 1 | | | | | |
| Comparative | 4.0 | 15.4 | 0.68 | 0.32 | 230 |
| Example 2 | | | | | |
| Comparative | 8.8 | 4.1 | 0.66 | 0.35 | 10 |
| Example 3 | | | | | |
| Comparative | 8.5 | 3.4 | 0.66 | 0.35 | 10 |
| Example 4 | | | | | |

Referring to Table 1, it was confirmed that the devices of Examples had low driving voltage and improved efficiency and lifespan, as compared with the devices of the Comparative Examples.

The light-emitting devices of the Examples exhibit excellent results compared to those of the Comparative Examples 1 and 2, which do not have a hole injection layer that includes graphene. The hole injection layer of the Examples appears to have excellent hole injection capability than the devices of Comparative Examples 1 and 2. Moreover, the graphene appears to physically block the solvent, out-gassing, and the like from the inside of the light-emitting device, thereby preventing damage to the anode.

The light-emitting devices of Comparative Examples 3 and 4 exhibit relatively poor results compared to the Examples devices. The graphene used in the hole injection layer of Comparative Examples 3 and 4 is oxidized or brominated, and thus, the degree of physical deposition of the HIL appears not to be as good as that of pure graphene. Accordingly, physical blocking of the solvent, out-gassing, and the like from the inside of the light-emitting device is incomplete, thereby causing damage to the anode.

As described above, according to the one more embodiments, a light-emitting device may exhibit improved performance as compared with devices of the related art.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A light-emitting device comprising:
a first electrode;
a second electrode facing the first electrode; and
an interlayer located between the first electrode and the second electrode and comprising an emission layer,
wherein the interlayer further comprises a hole injection layer that includes graphene and the hole injection layer disposed between the emission layer and contacts the second electrode, and
wherein the first electrode is a cathode.

2. The light-emitting device of claim 1, wherein the first electrode comprises indium tin oxide (ITO), indium zinc oxide (IZO), tin oxide (SnO₂), zinc oxide (ZnO), or any combination thereof.

3. The light-emitting device of claim 1, wherein the first electrode comprises silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), indium (In), or any combination thereof.

4. The light-emitting device of claim 1, wherein a thickness of the hole injection layer is in a range of about 0.2 nanometers to about 200 nanometers.

5. The light-emitting device of claim 1, wherein
the second electrode is an anode, and
the interlayer further comprises a hole transport region disposed between the second electrode and the emission layer and including a hole transport layer, an electron blocking layer, or any combination thereof.

6. The light-emitting device of claim 5, wherein the hole transport layer comprises an oxide of: W; Ni; Mo; Cu; V; or any combination thereof.

7. The light-emitting device of claim 5, wherein the hole transport layer comprises a compound comprising at least one of moieties 1 to 11, wherein a point of attachment of the moiety to the compound is at any substitutable atom of the moiety, and each moiety is independently substituted or unsubstituted:

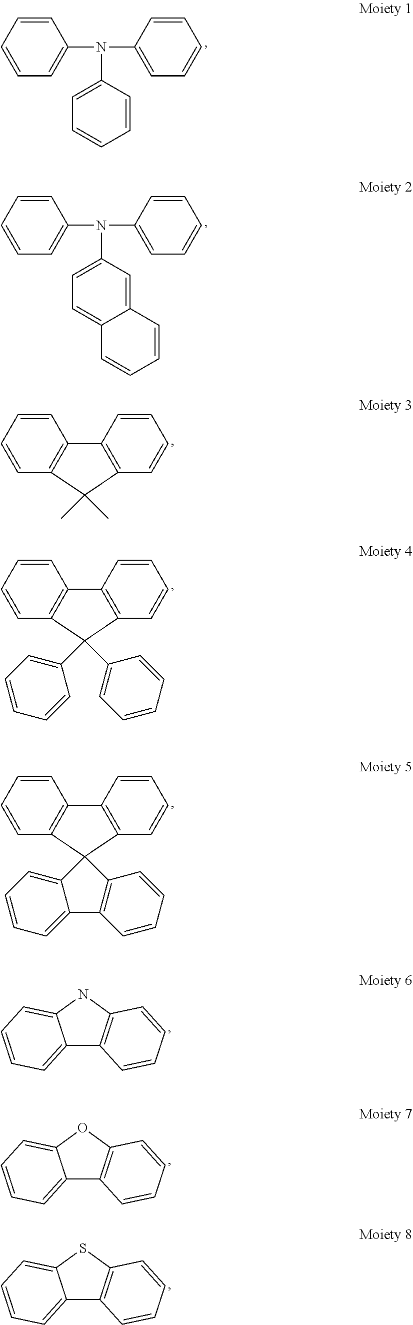

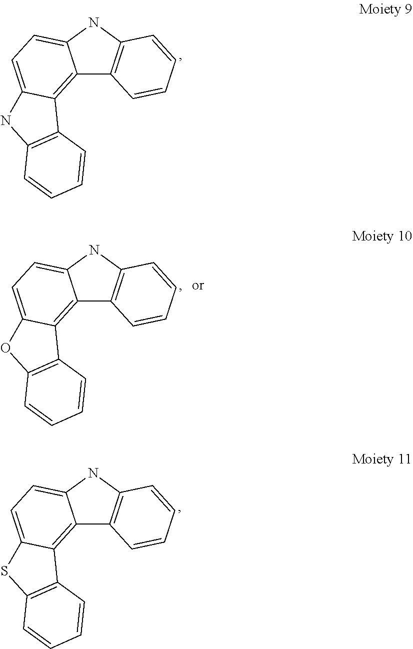 [SMILES: c1ccc2c(c1)[nH]c1ccc3[nH]c4ccccc4c3c12 ; c1ccc2c(c1)[nH]c1ccc3oc4ccccc4c3c12 ; c1ccc2c(c1)[nH]c1ccc3sc4ccccc4c3c12]

8. The light-emitting device of claim 5, wherein the hole transport layer comprises 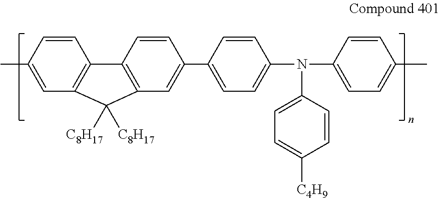
wherein, in Compound 401, n2 is an integer from 2 to 300, or 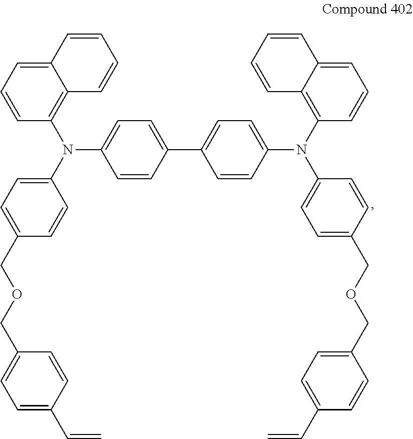 [SMILES: C=Cc1ccc(COCc2ccc(N(c3ccc(-c4ccc(N(c5ccc(COCc6ccc(C=C)cc6)cc5)c5cccc6ccccc56)cc4)cc3)c3cccc4ccccc34)cc2)cc1]
or
a combination thereof.

9. The light-emitting device of claim 1, further comprising an electron transport region that disposed between the first electrode and the emission layer, the electron transport region including an electron injection layer, an electron transport layer, a hole blocking layer, or any combination thereof.

10. The light-emitting device of claim 9, wherein the electron injection layer comprises an oxide of: Zn; Ti; Zr; Sn; Mg; Co; Ni; Mn; Y; Al; or any combination thereof.

11. The light-emitting device of claim 9, wherein the electron transport layer comprises a phosphine oxide compound.

12. The light-emitting device of claim 11, wherein the phosphine oxide compound comprises at least one of the compounds as follows

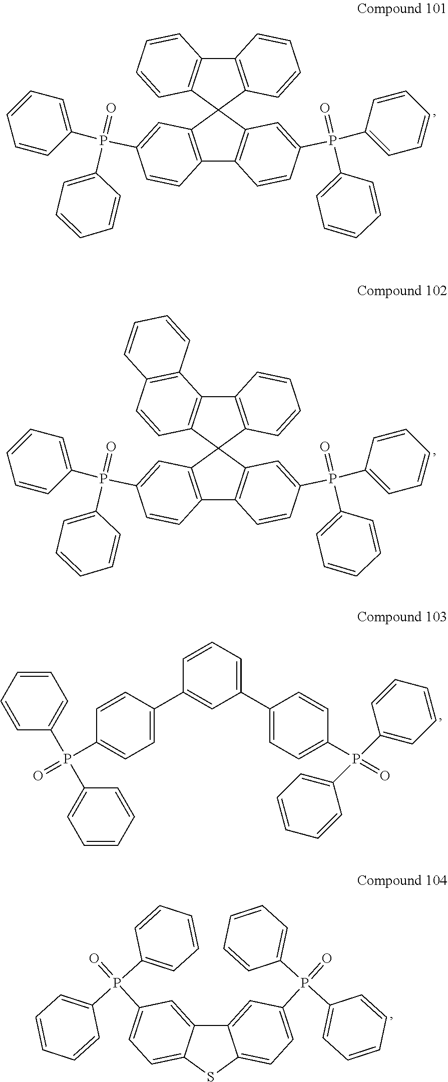 [SMILES: O=P(c1ccccc1)(c1ccccc1)c1ccc2c(c1)C1(c3ccccc3-c3ccccc31)c1cc(P(=O)(c3ccccc3)c3ccccc3)ccc1-2 ; O=P(c1ccccc1)(c1ccccc1)c1ccc2c(c1)C1(c3cc(P(=O)(c4ccccc4)c4ccccc4)ccc3-2)c2ccccc2-c2c1ccc1ccccc21 ; O=P(c1ccccc1)(c1ccccc1)c1ccc(-c2cccc(-c3ccc(P(=O)(c4ccccc4)c4ccccc4)cc3)c2)cc1 ; O=P(c1ccccc1)(c1ccccc1)c1ccc2sc3ccc(P(=O)(c4ccccc4)c4ccccc4)cc3c2c1]

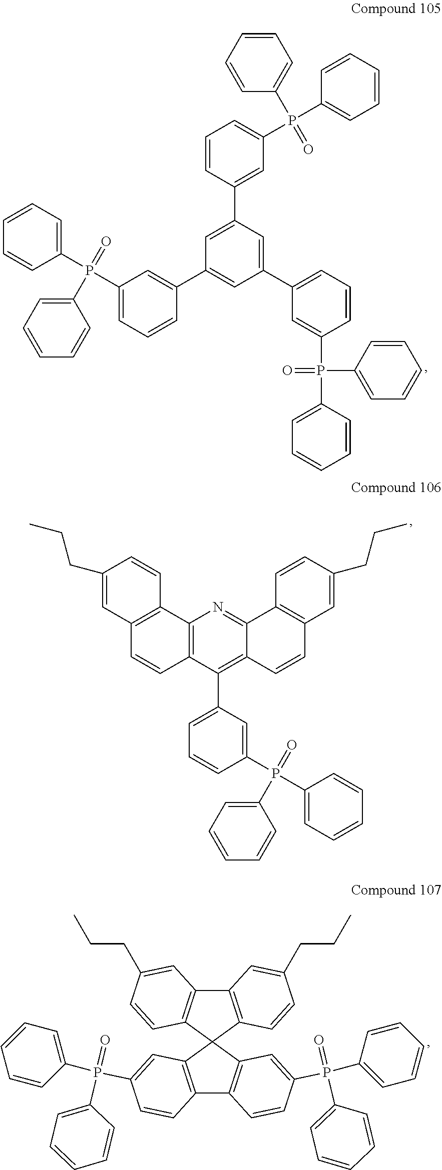 [SMILES: O=P(c1ccccc1)(c1ccccc1)c1cccc(-c2cc(-c3cccc(P(=O)(c4ccccc4)c4ccccc4)c3)cc(-c3cccc(P(=O)(c4ccccc4)c4ccccc4)c3)c2)c1 ; CCCc1ccc2c(ccc3c(-c4cccc(P(=O)(c5ccccc5)c5ccccc5)c4)c4ccc5cc(CCC)ccc5c4nc32)c1 ; CCCc1ccc2c(c1)-c1cc(CCC)ccc1C21c2cc(P(=O)(c3ccccc3)c3ccccc3)ccc2-c2ccc(P(=O)(c3ccccc3)c3ccccc3)cc21]

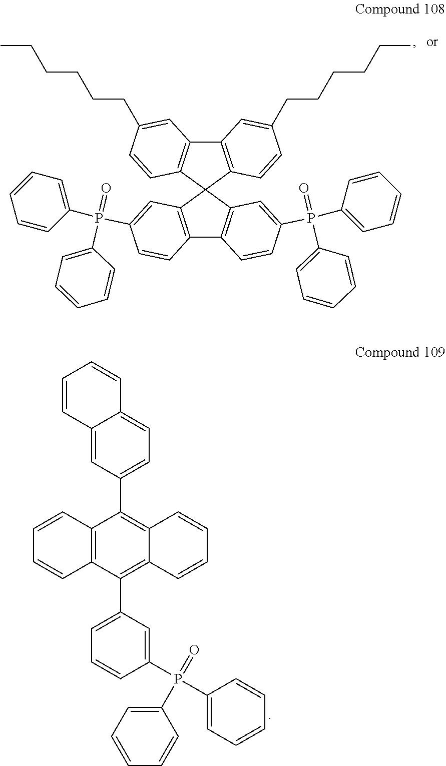 [SMILES: CCCCCCc1ccc2c(c1)-c1cc(CCCCCC)ccc1C21c2cc(P(=O)(c3ccccc3)c3ccccc3)ccc2-c2ccc(P(=O)(c3ccccc3)c3ccccc3)cc21 ; O=P(c1ccccc1)(c1ccccc1)c1cccc(-c2c3ccccc3c(-c3ccc4ccccc4c3)c3ccccc23)c1]

13. The light-emitting device of claim 9, wherein the electron transport region includes the electron transport layer, and the electron transport layer comprises a metal-containing material.

14. The light-emitting device of claim 13, wherein the metal-containing material comprises at least one of the compounds as follows:

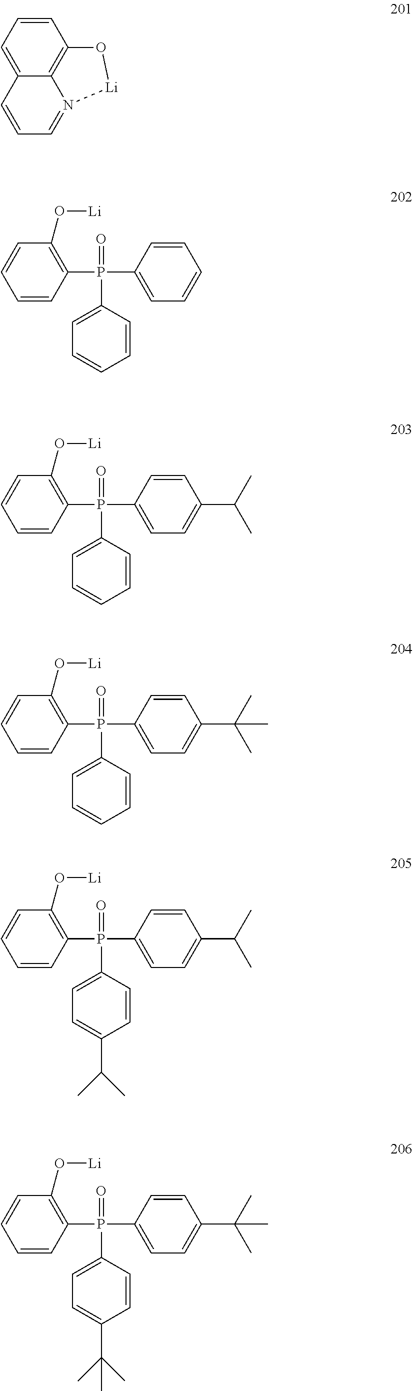

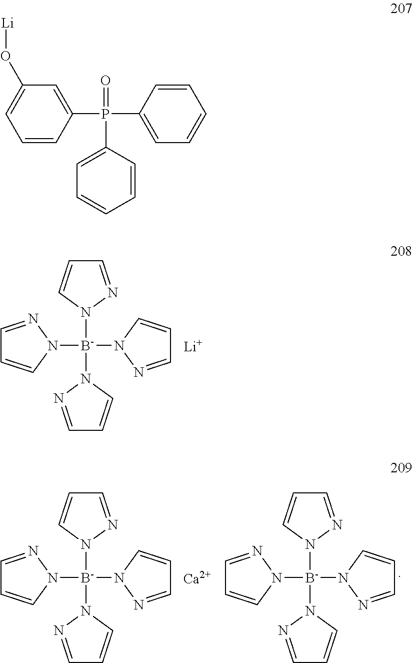

15. The light-emitting device of claim 1, wherein the interlayer comprises a layer formed by curing a composition comprising at least one compound represented by Formula 1:
N₃—(R₁)ₘ—N₃ Formula 1
wherein, in Formula 1:
R₁ is a divalent C₃-C₆₀ carbocyclic group unsubstituted or substituted with at least one R₁₀ₐ, a divalent C₁-C₆₀ heterocyclic group unsubstituted or substituted with at least one R₁₀ₐ, a C₁-C₆₀ alkylene group unsubstituted or substituted with at least one R₁₀ₐ, a C₂-C₆₀ alkenylene group unsubstituted or substituted with at least one R₁₀ₐ, or a C₂-C₆₀ alkynylene group unsubstituted or substituted with at least one R₁₀ₐ, —O—, —Si(Q₁)(Q₂)-, —B(Q₁)-, —N(Q₁)-, —P(Q₁)-, —C(═O)—, —S(═O)—, —S(═O)₂—, —P(═O)Q₁-, —P(═S)Q₁-, or a combination thereof, and m is an integer from 1 to 10;
wherein R₁₀ₐ is
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂),
wherein Q₁, Q₂, Q₁ to Q₁₃, Q₂₁ to Q₂₃, and Q₃₁ to Q₃₃ are each independently:
hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; or a C₃-C₆₀ carbocyclic group, a C₁-C₆₀ heterocyclic group, a C₇-C₆₀ arylalkyl group, or a C₂-C₆₀ heteroarylalkyl group, each unsubstituted or substituted with deuterium, —F, a cyano group, a C₁-C₆₀ alkyl group, a C₁-C₆₀ alkoxy group, a phenyl group, a biphenyl group, or any combination thereof.

16. The light-emitting device of claim 15, wherein the compound of Formula 1 includes at least one of the compounds

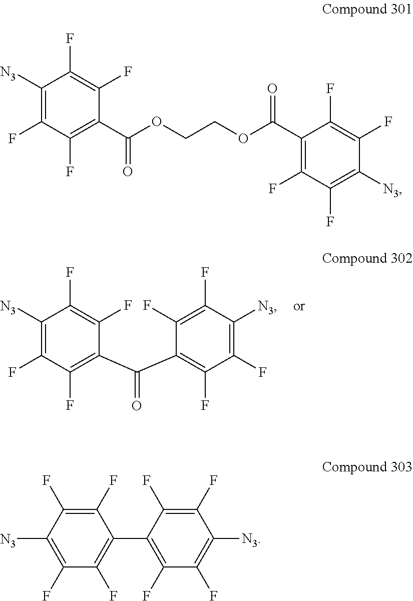 [SMILES: [N-]=[N+]=Nc1c(F)c(F)c(C(=O)OCCOC(=O)c2c(F)c(F)c(N=[N+]=[N-])c(F)c2F)c(F)c1F ; [N-]=[N+]=Nc1c(F)c(F)c(C(=O)c2c(F)c(F)c(N=[N+]=[N-])c(F)c2F)c(F)c1F ; [N-]=[N+]=Nc1c(F)c(F)c(-c2c(F)c(F)c(N=[N+]=[N-])c(F)c2F)c(F)c1F]

17. The light-emitting device of claim 15, wherein the layer formed by curing the composition comprising the compound of Formula 1 is the emission layer and/or the electron transport layer.

18. The light-emitting device of claim 1, wherein the emission layer comprises a quantum dot.

19. An electronic apparatus comprising the light-emitting device of claim 1.

20. The electronic apparatus of claim 19, further comprising a thin-film transistor, wherein
the thin-film transistor comprises a source electrode and a drain electrode, and
the first electrode of the light-emitting device is electrically connected to at least one of the source electrode or the drain electrode of the thin-film transistor.
